(19) United States
(12) Patent Application Publication
(10) Pub. No.: US 2022/0337202 A1
(43) Pub. Date: Oct. 20, 2022

(54) LIGHT-CONTROLLED CURRENT AMPLIFYING CIRCUIT

(71) Applicant: CHIH HSIEN YUAN, Taoyuan City (TW)

(72) Inventor: CHIH HSIEN YUAN, Taoyuan City (TW)

(21) Appl. No.: 17/696,196

(22) Filed: Mar. 16, 2022

(30) Foreign Application Priority Data
Apr. 19, 2021 (TW) 110114016

(51) Int. Cl. H03F 3/08; H05B 47/10

(52) U.S. Cl. CPC H03F 3/082; H05B 47/10

(57) ABSTRACT

A current amplifying circuit includes a first FET transistor, a light receiving unit and a functional unit. The light receiving unit is connected with a first gate terminal of the first FET transistor through an enabling line. The functional unit is connected with a second conduction terminal of the first FET transistor. When the light receiving unit absorbs a light beam, a forward photoelectric current or a reverse photoelectric current is generated. The forward photoelectric current or the reverse photoelectric current flows to the first gate terminal through the enabling line. Consequently, an enabling voltage at the first gate terminal is increased and the first FET transistor is turned on. When the first FET transistor is turned on, an enabling current flows through the first FET transistor to enable the functional unit.

### FIELD OF THE INVENTION

The present invention relates to a current amplifying circuit, and more particularly to a light-controlled current amplifying circuit for controlling an electronic component according to the current generated by an optical sensor.

### BACKGROUND OF THE INVENTION

As known, the early microwave amplifiers usually use vacuum tubes as amplifying components. Generally, the vacuum tube has a larger gain-bandwidth (GBW) product, and its output power is larger. However, the vacuum tube is relatively bulky and has a short service life. In addition, the vacuum tube has some other disadvantages such as high heat generation and high power consumption. Consequently, vacuum tubes are not suitably installed in today's thin and miniature portable electronic devices. With the advancement of the semiconductor manufacturing process, transistors have gradually become the components for achieving the function of microwave amplification. However, transistors still have some drawbacks. For example, the gain magnification is usually too small. Take the widely used BJT transistor for example. The BJT transistor can only achieve the current amplification of about 100 times.

In order to overcome the drawbacks of the conventional technology, it is important to provide a current amplifying circuit with a large gain magnification.

### SUMMARY OF THE INVENTION

An object of the present invention provides a current amplifying circuit with a large gain magnification. The current amplifying circuit is a light-controlled current amplifying circuit for controlling an electronic component according to the weak current generated by an optical sensor. The current amplifying circuit uses a FET transistor that is controlled according to a voltage signal. By applying the voltage signal to the gate terminal of the FET transistor, the extent of the current conduction between the other two conduction terminals of the FET transistor is controllable.

In accordance with an aspect of the present invention, a current amplifying circuit is provided. The current amplifying circuit includes a first FET transistor, a light receiving unit and a functional unit. The first FET transistor has a first conduction terminal, a first gate terminal and a second conduction terminal. The light receiving unit is connected with the first gate terminal through an enabling line. The functional unit is connected with the second conduction terminal. When the light receiving unit absorbs a light beam, the light receiving unit generates a forward photoelectric current or a reverse photoelectric current. The forward photoelectric current or the reverse photoelectric current flows to the first gate terminal through the enabling line. Consequently, an enabling voltage at the first gate terminal is increased and the first FET transistor is turned on. When the first FET transistor is turned on, an enabling current flows through the first conduction terminal and the second conduction terminal to enable the functional unit.

In an embodiment, the current amplifying circuit further include a guiding line. A first terminal of the guiding line is connected with the light receiving unit. A second terminal of the guiding line receives a guiding voltage. In response the guiding voltage, electric charges accumulated at the first gate terminal are guided and discharged through the guiding line. Consequently, the enabling voltage is decreased, and the first FET transistor is turned off.

In an embodiment, the electric charges are gradually accumulated at the first gate terminal within an enabling period, and a magnitude of the enabling voltage reaches an upper limit at an end of the enabling period. After the enabling period, the electric charges accumulated at the first gate terminal are gradually discharged within a disabling period.

In an embodiment, the current amplifying circuit further includes a second FET transistor. The second FET transistor has a third conduction terminal, a second gate terminal and a fourth conduction terminal. The third conduction terminal is connected with the first gate terminal. When the second FET transistor is turned on, electric charges accumulated at the first gate terminal are guided and discharged through the third conduction terminal and the fourth conduction terminal. Consequently, the enabling voltage is decreased, and the first FET transistor is turned off.

In an embodiment, the electric charges are gradually accumulated at the first gate terminal within an enabling period, and a magnitude of the enabling voltage reaches an upper limit at an end of the enabling period. After the enabling period, the electric charges accumulated at the first gate terminal are gradually discharged within a disabling period.

In an embodiment, the current amplifying circuit further includes a BJT transistor. The BJT transistor has a fifth conduction terminal, a base terminal and a sixth conduction terminal. The enabling line includes a first conductor line and a second conductor line. A first terminal of the first conductor line is connected with the light receiving unit. A second terminal of the first conductor line is connected with the base terminal. A first terminal of the second conductor line is connected with the sixth conduction terminal. A second terminal of the second conductor line is connected with the first gate terminal. The forward photoelectric current or the reverse photoelectric current flows to the base terminal through the first conductor line. Consequently, the BJT transistor is turned on. When the BJT transistor is turned on, an amplified current flows to the first gate terminal through the fifth conduction terminal and the sixth conduction terminal. Consequently, the enabling voltage is increased, and the first FET transistor is turned on.

In an embodiment, when the fifth conduction terminal receives a guiding voltage, electric charges accumulated at the first gate terminal are guided and discharged through the BJT transistor. Consequently, the enabling voltage is decreased and the first FET transistor is turned off.

In an embodiment, the current amplifying circuit further includes a second FET transistor. The second FET transistor has a third conduction terminal, a second gate terminal and a fourth conduction terminal. The third conduction terminal is connected with the first gate terminal. When the second FET transistor is turned on, electric charges accumulated at the first gate terminal are guided and discharged through the third conduction terminal and the fourth conduction terminal. Consequently, the enabling voltage is decreased, and the first FET transistor is turned off.

In an embodiment, the functional unit is a light emitting unit, a current readout unit or a current storage unit.

The light-controlled current amplifying circuit of the present invention is advantageous over the conventional current amplifying circuit. The circuitry structure of the light-controlled current amplifying circuit of the present invention is simple. In comparison with the conventional BJT transistor capable of providing the current amplification of 100 times, the light-controlled current amplifying circuit of the present invention can provide the current amplification of more than ten thousand times. The current amplifying circuit of the present invention is suitably applied to the optical amplification field such the optical signal detection application or the night vision system.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a flowchart illustrating a method for manufacturing an optical amplifying module according to an embodiment of the present invention;

FIG. 1 is a schematic cross-sectional view illustrating an optical amplifying module of the present invention;

FIG. 2A is a schematic circuit diagram illustrating a light-controlled current amplifying circuit according to a first embodiment of the present invention;

FIG. 2B is a plot illustrating the changes of the voltage and the current of the light-controlled current amplifying circuit as shown in FIG. 2A;

FIG. 3 is a schematic circuit diagram illustrating a light-controlled current amplifying circuit according to a second embodiment of the present invention;

FIG. 4 is a schematic circuit diagram illustrating a light-controlled current amplifying circuit according to a third embodiment of the present invention; and

FIG. 5 is a schematic circuit diagram illustrating a light-controlled current amplifying circuit according to a fourth embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

The present invention provides a light-controlled current amplifying circuit for an optical amplifying module. The optical amplifying module is manufactured by using optoelectronic semiconductor manufacturing processes.

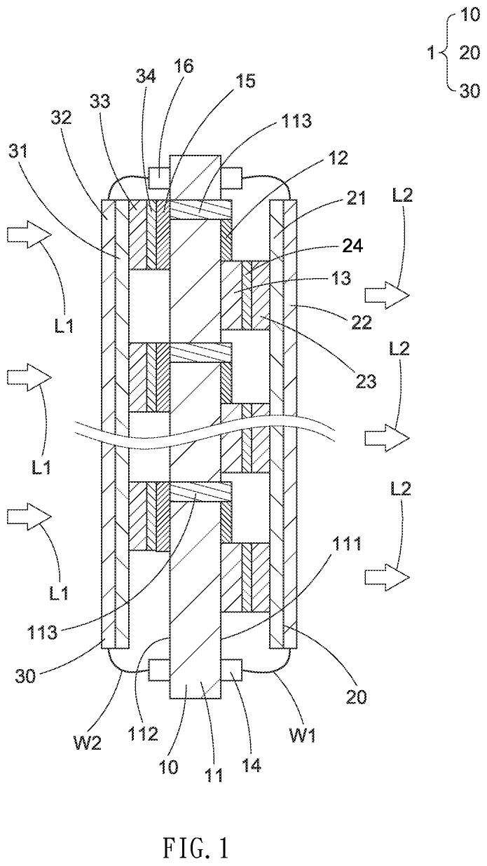

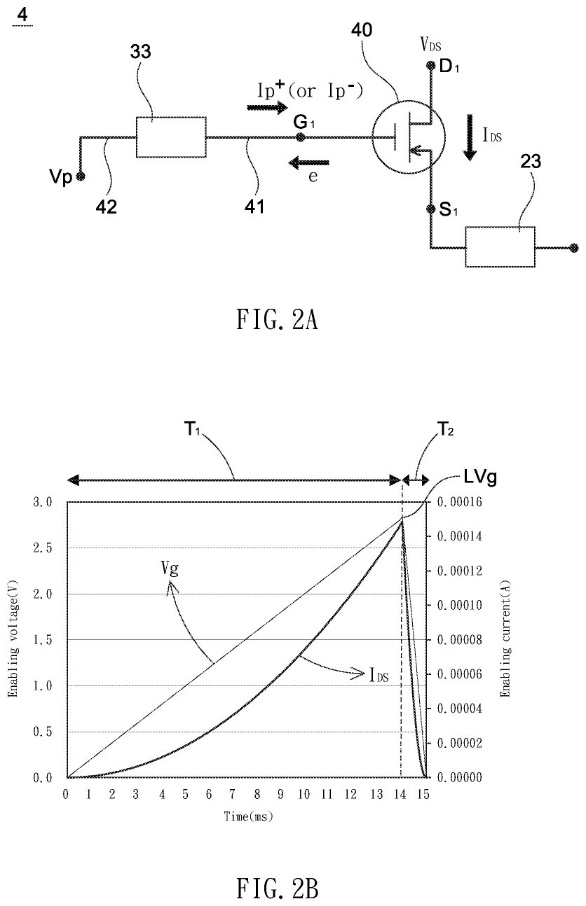

Please refer to FIGS. 1, 2A and 2B. FIG. 1 is a schematic cross-sectional view illustrating an optical amplifying module of the present invention. FIG. 2A is a schematic circuit diagram illustrating a light-controlled current amplifying circuit according to a first embodiment of the present invention. FIG. 2B is a plot illustrating the changes of the voltage and the current of the light-controlled current amplifying circuit as shown in FIG. 2A.

Please refer to FIG. 1. The optical amplifying module 1 comprises a current amplifying element 10, a light emitting element 20, and a light receiving element 30. A main substrate 11 of the current amplifying element 10 comprises a first surface 111 and a second surface 112, which are opposed to each other. Moreover, plural first main electrodes 13, plural transistors 12 and at least one first minor electrode 14 are installed on the first surface 111 of the main substrate 11. Each transistor 12 is located beside the corresponding first main electrode 13. In addition, each transistor 12 is electrically connected with the corresponding first main electrode 13. Moreover, plural second main electrodes 15 and at least one second main electrode 16 are installed on the second surface 112 of the main substrate 11. Each transistor 12 is electrically connected with the corresponding second main electrode 15 through a corresponding inner conductor line 113. Moreover, each transistor 12 comprises a portion of the light-controlled current amplifying circuit as shown in FIG. 2A.

The light emitting element 20 comprises a first light-transmissible electrode 22 and plural functional units 23 corresponding to the first main electrodes 13. Each functional unit 23 comprises a first connection electrode 24. In this embodiment, the first light-transmissible electrode 22 is a multi-layered structure. The functional unit 23 is a light emitting unit. The first light-transmissible electrode 22 and the functional unit 23 are formed on the two opposite surfaces of the first light-transmissible substrate 21. The first connection electrode 24 is formed on a surface of the corresponding functional unit 23 away from the first light-transmissible electrode 21. Under this circumstance, each functional unit 23 is electrically coupled with the corresponding first main electrode 13 through the first connection electrode 24. The first light-transmissible electrode 22 is electrically coupled with the at least one first minor electrode 14 through at least one first conductive wire W1.

The light receiving element 30 comprises a second light-transmissible electrode 32 and plural light receiving units 33 corresponding to the second main electrodes 15. Each light receiving unit 33 comprises a second connection electrode 34. In this embodiment, the second light-transmissible electrode 32 is a multi-layered structure. The second light-transmissible electrode 32 and the light receiving unit 33 are formed on the two opposite surfaces of the second light-transmissible substrate 31. The second connection electrode 34 is formed on a surface of the corresponding light emitting receiving unit 33 away from the second light-transmissible electrode 31. Under this circumstance, each light receiving unit 33 is electrically coupled with each second main electrode 15 through the corresponding second connection electrode 34. The second light-transmissible electrode 32 is electrically coupled with the at least one second minor electrode 16 through at least one second conductive wire W2.

The optical amplifying module 1 can be installed in a night vision device (not shown). For example, the night vision device is a night vision goggle. A lens (not shown) for refracting light beams is located beside the light receiving element 30 of the optical amplifying module 1. Moreover, a power source of the night vision device is electrically connected with the main substrate 11 or the first light-transmissible substrate 21 in order to provide electric power to the optical amplifying module 1. After an ambient light beam L1 is irradiated on the light receiving element 30, the received light beam is converted into a current signal by the light receiving units 33. The current signal is transmitted to the transistors 12 through the second main electrodes 15 and the inner conductor lines 113. After the transistors 12 receive the current signal, the functional units in the transistors are driven by the electricity from the night vision device. Afterwards, the amplified start current is driven into the functional units 23 (i.e., the light emitting units) through the first main electrodes 13. Consequently, the functional units 23 emit a displaying light beam L2 with the stronger intensity. The displaying light beam L2 generated by the light emitting element 20 can be formed as the visible light image corresponding to the ambient light beam L1. The visible light image can be recognized by the user.

In the above embodiment, the functional unit 23 is a light emitting unit. It is noted that the examples of the functional unit 23 are not restricted. For example, in another embodiment, the functional unit 23 is a current readout unit (e.g., an electricity meter) or a current storage unit (e.g., a capacitor or a battery).

Please refer to FIGS. 1 and 2A. The light-controlled current amplifying circuit 4 comprises a first FET transistor 40, an enabling line 41, a guiding line 42, a light receiving unit 33 and a functional unit 23. The first FET transistor 40 has a first conduction terminal D₁ (e.g., a drain terminal), a first gate terminal G₁ and a second conduction terminal S₁ (e.g., a source terminal). The light receiving unit 33 is connected with the first gate terminal G₁ of the first FET transistor 40 through the enabling line 41. The functional unit 23 is connected with the second conduction terminal S₁ of the first FET transistor 40. A first terminal of the guiding line 42 is connected with the light receiving unit 33. The first conduction terminal D₁ of the first FET transistor 40 receives a loading voltage V_{DS}.

Please refer to FIGS. 2A and 2B. After the light receiving unit 33 absorbs the ambient light beam L1, one of a forward photoelectric current Ip⁺ (positive) or a reverse photoelectric current Ip⁻ (negative) is generated. The forward photoelectric current Ip⁺ or the reverse photoelectric current Ip⁻ is related to polarity of electricity and circuit design. For example, the electrons corresponding to the forward photoelectric current Ip⁺ move in direction from the first gate terminal G₁ to the light receiving unit 33. The electrons corresponding to the reverse photoelectric current Ip⁻ move in direction from the light receiving unit 33 to the first gate terminal G₁. The forward photoelectric current Ip⁺ or the reverse photoelectric current Ip⁻ flows to the first gate terminal G₁ through the enabling line 41. Consequently, the enabling voltage V_{g} at the first gate terminal G₁ is increased so as to turn on the first FET transistor 40. When the first FET transistor 40 is turned on, an enabling current IDS is generated according to the loading voltage V_{DS} at the first conduction terminal D₁. The enabling current IDS flows through the first conduction terminal D₁ and the second conduction terminal S₁ so as to enable the functional unit 23.

For turning off the first FET transistor 40, a waveform generator (not shown) is used to generate a reverse voltage. As mentioned above, the first terminal of the guiding line 42 is connected with the light receiving unit 33. In addition, a second terminal of the guiding line 42 receives a guiding voltage Vₚ. The electric charges e accumulated at the first gate terminal G₁ are guided and discharged through the guiding line 42. As the enabling voltage V_{g} is gradually decreased, the first FET transistor 40 is turned off.

Please refer to FIG. 2B again. In FIG. 2B, the bottom horizontal axis represents time in the unit of millisecond (ms), the left vertical axis represents the value of the enabling voltage V_{g} in the unit of volt (V), and the right vertical axis represents the value of the enabling current IDS in the unit of ampere (A). As the forward photoelectric current Ip⁺ flows to the first gate terminal G₁, the electric charges are gradually accumulated at the first gate terminal G₁, and the magnitude of the enabling voltage V_{g} is gradually increased. Consequently, after an enabling period T₁, the enabling voltage V_{g} reaches an upper limit LV_{g}. As the magnitude of the enabling voltage V_{g} is increased, the magnitude of the enabling current IDS is increased.

When the guiding voltage Vₚ is generated, the electric charges accumulated at the first gate terminal G₁ are gradually discharged. After a disabling period T₂, the first FET transistor 40 is turned off. As the magnitude of the enabling voltage V_{g} is decreased, the magnitude of the enabling current IDS is gradually decreased.

In the above embodiment, the enabling voltage V_{g} is a positive voltage. It is noted that the polarity of the enabling voltage V_{g} is not restricted. For example, in another embodiment, the enabling voltage V_{g} is a negative voltage.

It is assumed that the conversion efficiency of the light receiving unit 33 is 30%. Consequently, when the light receiving unit 33 is operated under the illumination condition of 1×10⁻¹⁰ W/mm² (e.g., a red light with a wavelength of 620 nm), the light receiving unit 33 can output the forward photoelectric current Ip⁺ of 1.5×10⁻¹¹ A. In addition, the gate capacitance of the first gate terminal G₁ is 7.438×10⁻¹⁵ F. According to the settings, the enabling period T₁ is 14 ms, and the disabling period T₂ is 1 ms. The enabling voltage V_{g} at the first gate terminal G₁ of the first FET transistor 40 is gradually increased from 0V to the upper limit LV_{g} (e.g., 2.82 V) within the enabling period T₁. Consequently, the magnitude of the enabling current IDS flow through the first conduction terminal D₁ and the second conduction terminal S₁ of the first FET transistor 40. At the end of the enabling period T₁ (i.e., t=14 ms), the enabling current IDS is increased to 1.48×10⁻⁴ A. When compared with the forward photoelectric current Ip⁺ outputted from the light receiving unit 33, the current gain magnification of the enabling current IDS is 9.88×10⁶.

After the enabling period T₁, a discharging process is performed within the disabling period T₂ (e.g., 1 ms). As the enabling voltage V_{g} at the first gate terminal G₁ is decreased, the enabling current IDS is quickly decreased to 0 A.

By alternately performing the process of the enabling period T₁ and the process of the disabling period T₂, the current amplifying purpose can be achieved within the withstand voltage range of the first gate terminal G₁ of the first FET transistor 40.

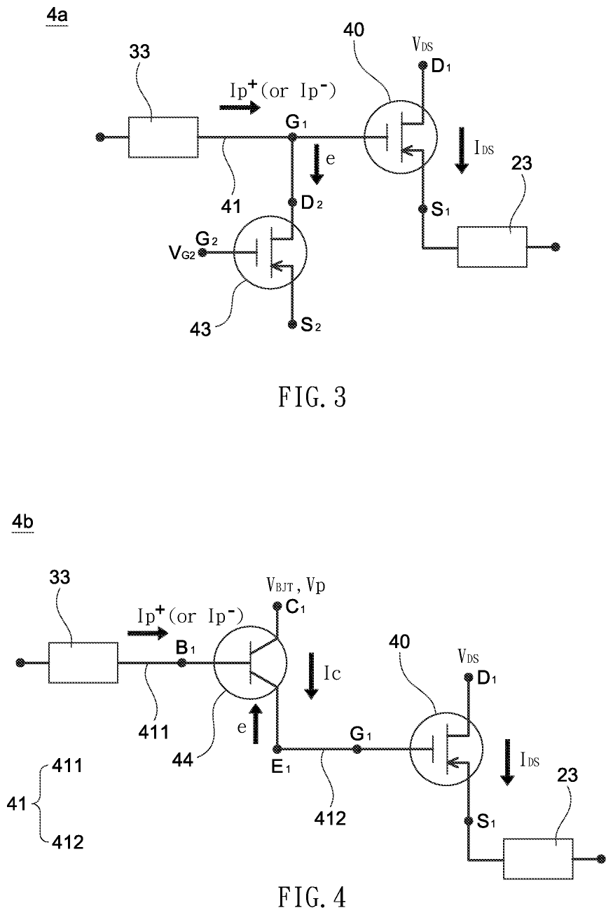

Please refer to FIG. 3. FIG. 3 is a schematic circuit diagram illustrating a light-controlled current amplifying circuit according to a second embodiment of the present invention. The structures and functions of the components of the light-controlled current amplifying circuit which are identical to those of the first embodiment as shown in FIG. 2A are not redundantly described herein. In comparison with the first embodiment, the light-controlled current amplifying circuit 4a of this embodiment is not equipped with the guiding line 42 to discharge the electric charges e. Moreover, the light-controlled current amplifying circuit 4a of this embodiment further comprises a second FET transistor 43. The second FET transistor 43 has a third conduction terminal D₂ (e.g., a drain terminal), a second gate terminal G₂ and a fourth conduction terminal S₂ (e.g., a source terminal). The third conduction terminal D₂ is connected with the first gate terminal G₁. For turning off the first FET transistor 40, a waveform generator (not shown) is used to provide a loading voltage VG₂ to the second gate terminal G₂. In response to the loading voltage VG₂, the second FET transistor 43 is turned on. Consequently, the electric charges accumulated at the first gate terminal G₁ are guided and discharged through the second FET transistor 43. As the enabling voltage V_{g} is gradually decreased, the first FET transistor 40 is turned off.

Please refer to FIG. 4. FIG. 4 is a schematic circuit diagram illustrating a light-controlled current amplifying circuit according to a third embodiment of the present invention. The structures and functions of the components of the light-controlled current amplifying circuit which are identical to those of the first embodiment as shown in FIG. 2A are not redundantly described herein. In comparison with the first embodiment, the light-controlled current amplifying circuit 4c of this embodiment is not equipped with the guiding line 42 to discharge the electric charges e. Moreover, the light-controlled current amplifying circuit 4b of this embodiment further comprises a BJT transistor 44. In this embodiment, the BJT transistor 44 has a fifth conduction terminal C₁ (e.g., a collector), a base terminal B₁ and a sixth conduction terminal E₁ (e.g., an emitter). The enabling line 41 comprises a first conductor line 411 and a second conductor line 412. A first terminal of the first conductor line 411 is connected with the light receiving unit 33. A second terminal of the first conductor line 411 is connected with the base terminal B₁. A first terminal of the second conductor line 412 is connected with the sixth conduction terminal E₁. A second terminal of the second conductor line 412 is connected with the first gate terminal G₁. The forward photoelectric current Ip⁺ or the reverse photoelectric current Ip⁻ flows to the base terminal B₁ through the first conductor line 411 of the enabling line 41. Consequently, the BJT transistor 44 is turned on. The fifth conduction terminal C₁ receives a loading voltage V_{BJT}. In response to the loading voltage V_{BJT}, an amplified current I_{C} flows to the first gate terminal G₁ through the fifth conduction terminal C₁ and the sixth conduction terminal E₁. In this way, the enabling voltage V_{g} at the first gate terminal G₁ is increased so as to turn on the first FET transistor 40.

For turning off the first FET transistor 40, a waveform generator (not shown) is used to provide a guiding voltage Vₚ to the fifth conduction terminal C₁. In response to the guiding voltage Vₚ, the electric charges accumulated at the first gate terminal G₁ are guided and discharged. As the enabling voltage V_{g} is decreased, the first FET transistor 40 is turned off.

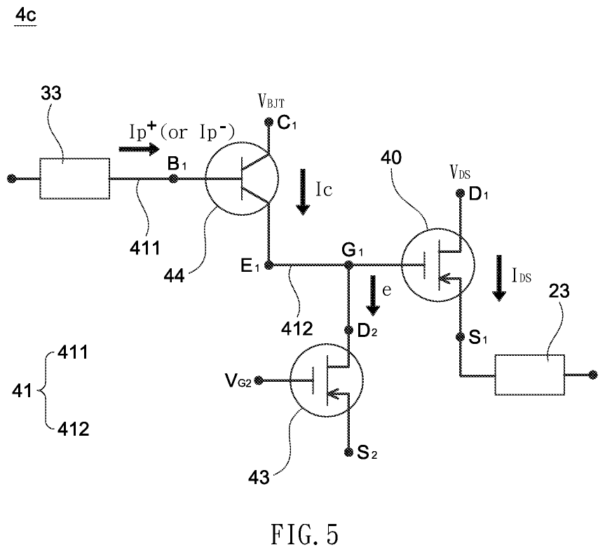

Please refer to FIG. 5. FIG. 5 is a schematic circuit diagram illustrating a light-controlled current amplifying circuit according to a fourth embodiment of the present invention. The structures and functions of the components of the light-controlled current amplifying circuit which are identical to those of the third embodiment as shown in FIG. 4 are not redundantly described herein. In comparison with the third embodiment, the light-controlled current amplifying circuit 4c of this embodiment further comprises a second FET transistor 43. The second FET transistor 43 has a third conduction terminal D₂ (e.g., a drain terminal), a second gate terminal G₂ and a fourth conduction terminal S₂ (e.g., a source terminal). The third conduction terminal D₂ is connected with the first gate terminal G₁. For turning off the first FET transistor 40, a waveform generator (not shown) is used to provide a loading voltage VG₂ to the second gate terminal G₂. In response to the loading voltage VG₂, the second FET transistor 43 is turned on. Consequently, the electric charges accumulated at the first gate terminal G₁ are guided and discharged through the second FET transistor 43. As the enabling voltage V_{g} is decreased, the first FET transistor 40 is turned off.

When compared with the conventional technologies, the present invention provides a current amplifying circuit with a large gain magnification. The circuitry structure of the current amplifying circuit is simplified. In other words, the technology of the present invention is industrially valuable.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A current amplifying circuit, comprising:
a first FET transistor having a first conduction terminal, a first gate terminal and a second conduction terminal;
a light receiving unit connected with the first gate terminal through an enabling line; and
a functional unit connected with the second conduction terminal,
wherein when the light receiving unit absorbs a light beam, the light receiving unit generates a forward photoelectric current or a reverse photoelectric current, wherein the forward photoelectric current or the reverse photoelectric current flows to the first gate terminal through the enabling line, so that an enabling voltage at the first gate terminal is increased and the first FET transistor is turned on, wherein when the first FET transistor is turned on, an enabling current flows through the first conduction terminal and the second conduction terminal to enable the functional unit.

2. The current amplifying circuit according to claim 1, wherein the current amplifying circuit further comprise a guiding line, wherein a first terminal of the guiding line is connected with the light receiving unit, and a second terminal of the guiding line receives a guiding voltage, wherein in response the guiding voltage, electric charges accumulated at the first gate terminal are guided and discharged through the guiding line, so that the enabling voltage is decreased and the first FET transistor is turned off.

3. The current amplifying circuit according to claim 2, wherein the electric charges are gradually accumulated at the first gate terminal within an enabling period, and a magnitude of the enabling voltage reaches an upper limit at an end of the enabling period, wherein after the enabling period, the electric charges accumulated at the first gate terminal are gradually discharged within a disabling period.

4. The current amplifying circuit according to claim 1, wherein the current amplifying circuit further comprises a second FET transistor, wherein the second FET transistor has a third conduction terminal, a second gate terminal and a fourth conduction terminal, and the third conduction terminal is connected with the first gate terminal, wherein when the second FET transistor is turned on, electric charges accumulated at the first gate terminal are guided and discharged through the third conduction terminal and the fourth conduction terminal, so that the enabling voltage is decreased and the first FET transistor is turned off.

5. The current amplifying circuit according to claim 4, wherein the electric charges are gradually accumulated at the first gate terminal within an enabling period, and a magnitude of the enabling voltage reaches an upper limit at an end of the enabling period, wherein after the enabling period, the electric charges accumulated at the first gate terminal are gradually discharged within a disabling period.

6. The current amplifying circuit according to claim 1, wherein the current amplifying circuit further comprises a BJT transistor, and the BJT transistor has a fifth conduction terminal, a base terminal and a sixth conduction terminal, wherein the enabling line comprises a first conductor line and a second conductor line, a first terminal of the first conductor line is connected with the light receiving unit, a second terminal of the first conductor line is connected with the base terminal, a first terminal of the second conductor line is connected with the sixth conduction terminal, and a second terminal of the second conductor line is connected with the first gate terminal, wherein the forward photoelectric current or the reverse photoelectric current flows to the base terminal through the first conductor line, so that the BJT transistor is turned on, wherein when the BJT transistor is turned on, an amplified current flows to the first gate terminal through the fifth conduction terminal and the sixth conduction terminal, so that the enabling voltage is increased and the first FET transistor is turned on.

7. The current amplifying circuit according to claim 6, wherein when the fifth conduction terminal receives a guiding voltage, electric charges accumulated at the first gate terminal are guided and discharged through the BJT transistor, so that the enabling voltage is decreased and the first FET transistor is turned off.

8. The current amplifying circuit according to claim 6, wherein the current amplifying circuit further comprises a second FET transistor, wherein the second FET transistor has a third conduction terminal, a second gate terminal and a fourth conduction terminal, and the third conduction terminal is connected with the first gate terminal, wherein when the second FET transistor is turned on, electric charges accumulated at the first gate terminal are guided and discharged through the third conduction terminal and the fourth conduction terminal, so that the enabling voltage is decreased and the first FET transistor is turned off.

9. The current amplifying circuit according to claim 1, wherein the functional unit is a light emitting unit, a current readout unit or a current storage unit.
